(19) United States
(12) Patent Application Publication
(10) Pub. No.: US 2023/0251575 A1
(43) Pub. Date: Aug. 10, 2023

(54) PHOTORESIST TOPCOAT COMPOSITIONS AND PATTERN FORMATION METHODS

(71) Applicant: Rohm and Haas Electronic Materials LLC, Marlborough, MA (US)

(72) Inventors: Irvinder Kaur, Northborough, MA (US); Doris H. Kang, Shrewsbury, MA (US); Cong Liu, Shrewsbury, MA (US)

(21) Appl. No.: 18/082,025

(22) Filed: Dec. 15, 2022

Related U.S. Application Data
(60) Provisional application No. 63/295,471, filed on Dec. 30, 2021.

(51) Int. Cl. G03F 7/11; G03F 7/16

(52) U.S. Cl. CPC G03F 7/11; G03F 7/162

(57) ABSTRACT

Photoresist topcoat compositions comprise: a first polymer that is fluorinated, a second polymer, and an organic-based solvent system comprising an ester solvent and one or more additional organic solvents, wherein the composition is substantially free of photoacid generator compounds. The invention finds particular applicability in the manufacture of semiconductor devices.

### FIELD OF THE INVENTION

This invention relates to photoresist topcoat compositions that may be applied above a photoresist composition. The invention further relates to pattern formation methods using the photoresist topcoat compositions. The invention finds particular applicability as a topcoat layer in an immersion lithography process for the formation of semiconductor devices.

### BACKGROUND OF THE INVENTION

Photoresists are used for transferring an image to a substrate. A layer of a photoresist is formed on a substrate and the photoresist layer is then exposed through a photomask to a source of activating radiation. The photomask has areas that are opaque to the activating radiation and other areas that are transparent to the activating radiation. Exposure to activating radiation provides a photoinduced chemical transformation of the photoresist coating to thereby transfer the pattern of the photomask to the photoresist-coated substrate. Following exposure, the photoresist is baked and developed by contact with a developer solution to provide a relief image that permits selective processing of the substrate.

To increase the integration density of semiconductor devices and allow for the formation of structures having dimensions in the nanometer range, photoresists and photolithography processing tools having high-resolution capabilities have been and continue to be developed. One approach to achieving nm-scale feature sizes in semiconductor devices is the use of activating radiation having a short wavelength, for example, 193 nm or less, for exposure of the photoresist layer. To further improve lithographic performance, immersion lithography tools have been developed to effectively increase the numerical aperture (NA) of the lens of the imaging device, for example, a scanner having an ArF (193 nm) light source. This is accomplished by use of a relatively high refractive index fluid, typically water, between the last surface of the imaging device and the upper surface of the semiconductor wafer.

In immersion lithography, direct contact between the immersion fluid and photoresist layer can result in leaching of components of the photoresist into the immersion fluid. This leaching can cause contamination of the optical lens and bring about a change in the effective refractive index and transmission properties of the immersion fluid. In an effort to address this problem, photoresist topcoat layers have been introduced as a barrier layer between the immersion fluid and underlying photoresist layer.

Topcoats exhibiting a low receding contact angle (RCA) for a given scan speed can result in water mark defects. These defects are generated when water droplets are left behind as the exposure head moves across the wafer. As a result, resist sensitivity becomes altered due to leaching of resist components into the water droplets, and water can permeate into the underlying resist. The use of self-segregating topcoat compositions has been proposed, for example, in Self-segregating Materials for Immersion Lithography, Daniel P. Sanders et al., Advances in Resist Materials and Processing Technology XXV, Proceedings of the SPIE, Vol. 6923, pp. 692309-1 - 692309-12 (2008), and in U.S. Pat. App. Pub. Nos. 2007/0212646A1 to Gallagher et al. and 2010/0183976A1 to Wang et al. A self-segregated topcoat would theoretically allow for a tailored material having desired properties at both the immersion fluid and photoresist interfaces, for example, an increased water receding contact angle at the immersion fluid interface, and good developer solubility at the photoresist interface.

Increases in receding contact angle can be achieved by use of topcoat materials having increased hydrophobicity at the immersion fluid interface, typically achieved through the use of a fluorinated polymer. In addition to allowing for reductions in water mark defects, increasing topcoat receding contact angle generally enables the use of an increased scan speed, resulting in greater process throughput. Despite such positive effects, the use of highly hydrophobic materials may negatively cause other defect types, for example, dewet coating defects which appear as spike-shaped coating discontinuities at the wafer periphery. Such defects can prevent proper formation of resist patterns and pattern transfer to underlying layers, thereby negatively impacting device yield. These defects may take the form, for example, of one or more of micro-bridging, missing contact holes, line pinching, or CD shift. A topcoat layer having a balance of high receding contact angle and low dewet coating defectivity levels would therefore be desired.

There is a continuing need in the art for improved photoresist topcoat compositions and photolithographic methods making use of such materials which address one or more problems associated with the state of the art.

### SUMMARY OF THE INVENTION

In accordance with a first aspect of the invention, provided are photoresist topcoat compositions. The compositions comprise:
a first polymer that is fluorinated, comprising:
   first polymerized units formed from a monomer of formula (1): 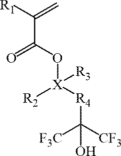
   wherein: R₁ represents a hydrogen atom, a fluorine atom, a C1-C4 alkyl group, or a C1-C4 fluoroalkyl group; R₂ and R₃ independently represent a hydrogen atom or a substituted or unsubstituted C1-C8 alkyl group; R₄ represents a substituted or unsubstituted C1-C4 alkylene group; and X represents a carbon atom, wherein: (i) at least one of R₂ and R₃ represents a substituted or unsubstituted C3-C8 cycloalkyl group; or (ii) at least one of R₂ and R₃ represents a substituted or unsubstituted C3-C8 alkyl group that comprises a branched structure when taken with X; or (iii) R₂ and R₃ together form a ring; and
   second polymerized units formed from a monomer of formula (2): 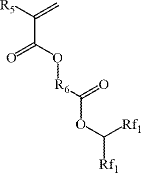
   wherein: R₅ represents a hydrogen atom, a fluorine atom, a C1-C4 alkyl group, or a C1-C4 fluoroalkyl group; R₆ represents a substituted or unsubstituted C1-C4 alkylene group; and Rf₁ independently represents a C1-C4 fluoroalkyl group;
   wherein: the total content of polymerized units of formula (1) in the first polymer is from 1 to 80 wt% based on total polymerized units of the first polymer; and wherein the first polymer is present in the composition in an amount of from 1 to 20 wt% based on total solids of the composition;
a second polymer; and
an organic-based solvent system comprising an ester solvent and one or more additional organic solvents;
wherein the composition is substantially free of photoacid generator compounds.

In accordance with a further aspect of the invention, provided are pattern formation methods. The methods comprise: (a) forming a photoresist layer on a substrate; (b) forming a photoresist topcoat layer on the photoresist layer, wherein the photoresist topcoat layer is formed from a photoresist topcoat composition as described herein; (c) exposing the photoresist topcoat layer and the photoresist layer to activating radiation; and (d) contacting the exposed topcoat layer and photoresist layer with a developer to form a resist pattern.

In accordance with a further aspect of the invention, provided are coated substrates. The coated substrates comprise: a photoresist layer on a substrate; and a photoresist topcoat layer formed from a photoresist topcoat composition as described herein on the photoresist layer.

As used herein, “substituted” means having one or more hydrogen atoms replaced with one or more substituents chosen, for example, from hydroxy, halogen (i.e., F, Cl, Br, I), C1-C10 alkyl, C6-C10 aryl, or a combination comprising at least one of the foregoing. The articles “a” and “an” are inclusive of one or more unless otherwise indicated.

### DETAILED DESCRIPTION

### Topcoat Compositions

The topcoat compositions of the invention comprise a first polymer that is fluorinated, a second polymer, and an organic-based solvent system comprising an ester solvent, and can include one or more additional, optional components.

Preferred topcoat compositions of the invention that are applied above a photoresist layer can minimize or prevent migration of components of the photoresist layer into an immersion fluid employed in an immersion lithography process. In preferred topcoat compositions of the invention, the first polymer is a surface active polymer that is self-segregating from other polymers of the composition during the coating process. As used herein, the term “immersion fluid” means a fluid, typically water, interposed between a lens of an exposure tool and a photoresist coated substrate to conduct immersion lithography.

Also as used herein, a topcoat layer will be considered as inhibiting the migration of photoresist material into an immersion fluid if a decreased amount of acid or organic material is detected in the immersion fluid upon use of the topcoat composition relative to the same photoresist system that is processed in the same manner, but in the absence of the topcoat composition layer. Detection of photoresist material in the immersion fluid can be conducted through mass spectroscopy analysis of the immersion fluid before exposure to the photoresist (with and without the overcoated topcoat composition layer) and then after lithographic processing of the photoresist layer (with and without the overcoated topcoat composition layer) with exposure through the immersion fluid. Preferably, the topcoat composition provides at least a 10 percent reduction in photoresist material (e.g., acid or organics as detected by mass spectroscopy) residing in the immersion fluid relative to the same photoresist that does not employ any topcoat layer (i.e., the immersion fluid directly contacts the photoresist layer), more preferably the topcoat composition provides at least a 20, 50, or 100 percent reduction in photoresist material residing in the immersion fluid relative to the same photoresist that does not employ a topcoat layer.

Preferred topcoat compositions of the invention can allow for improvement in defectivity characteristics, for example, in dewet coating defectivity. In addition, topcoat compositions of the invention can exhibit favorable contact angle characteristics, for example, receding contact angle (RCA), a characteristic at the immersion fluid interface that is important in an immersion lithography process in allowing for high scan speeds which translates to greater process throughput. The compositions can be used in dry lithography or more typically in immersion lithography processes. The exposure wavelength is not particularly limited except by the photoresist compositions, with wavelengths of less than 300 nm, for example, 248 nm, 193 nm or an EUV wavelength (e.g., 13.4 nm) being typical. Use of the compositions in a 193 nm immersion lithography process is particularly preferred.

Polymers useful in the invention are aqueous alkali soluble such that a topcoat layer formed from the composition can be removed in the resist development step using an aqueous alkaline developer, such as a quaternary ammonium hydroxide solution, for example, tetra methyl ammonium hydroxide (TMAH), typically 0.26 N aqueous TMAH.

A variety of polymers may be employed in the topcoat compositions of the invention, including polymers comprising polymerized acrylate groups, polyesters, or other repeat units and/or polymer backbone structures such as provided by, for example, poly(alkylene oxide), poly(meth)acrylic acid, poly (meth)acrylamides, polymerized aromatic (meth)acrylates, and polymerized vinyl aromatic monomers. Typically, the polymers include at least two different repeat units although the use of one or more homopolymers may be beneficial. The different polymers suitably may be present in varying relative amounts.

The polymers of the topcoat compositions of the invention may contain a variety of repeat units, including, for example, one or more: hydrophobic groups; weak acid groups; strong acid groups; branched optionally substituted alkyl or cycloalkyl groups; fluoroalkyl groups; or polar groups, such as ester, ether, carboxy, or sulfonyl groups. The presence of particular functional groups on the repeat units of the polymers will depend, for example, on the intended functionality of the polymer.

In certain preferred aspects, one or more polymers of the topcoat composition will comprise one or more groups that are reactive during lithographic processing, for example, one or more photoacid-acid labile groups that can undergo cleavage reactions in the presence of acid and heat, such as acid-labile ester groups (e.g., t-butyl ester groups such as provided by polymerization of t-butyl acrylate or t-butylmethacrylate, adamantylacrylate) and/or acetal groups such as provided by polymerization of a vinyl ether compound. The presence of such groups can render the associated polymer(s) more soluble in a developer solution, thereby aiding in developability and removal of the topcoat layer during a development process.

The polymers can advantageously be selected to tailor characteristics of the topcoat layer, with each generally serving one or more purpose or function. Such functions include, for example, one or more of photoresist profile adjusting, topcoat surface adjusting, reducing defects and reducing interfacial mixing between the topcoat and photoresist layers.

The topcoat compositions include one or more matrix polymers that may include one or more different types of repeat units, with two, or three different repeat units being typical. The matrix polymers preferably provide a sufficiently high developer dissolution rate for reducing overall defectivity due, for example, to micro-bridging. A typical developer dissolution rate for the matrix polymer is greater than 300 nm/second, preferably greater than 500 nm/second. The matrix polymers can be fluorinated or non-fluorinated. For some photoresist materials, fluorinated topcoat matrix polymers can reduce or minimize interfacial mixing between the topcoat layer and underlying photoresist layer. Accordingly, one or more repeating unit of the matrix polymer can be fluorinated, for example, with a fluoroalkyl group such as a C1 to C4 fluoroalkyl group, typically fluoromethyl, and may be present, for example, as a sulfonamide group (e.g., —NHSO₂CF₃) or a fluoroalcohol group (e.g., —C(CF₃)₂OH).

The matrix polymer has a higher surface energy than that of, and is preferably immiscible with, the surface active polymer, to allow the surface active polymer to phase separate from the matrix polymer and migrate to the upper surface of the topcoat layer away from the topcoat photoresist interface. The surface energy of the matrix polymer is typically from 30 to 60 mN/m.

Exemplary matrix polymers in accordance with the invention include the following:

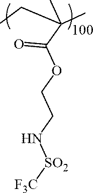

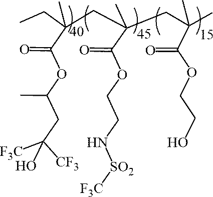

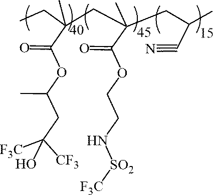

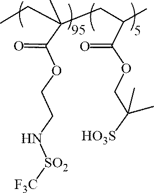

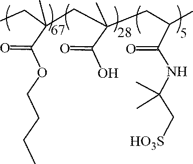

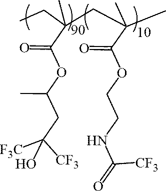

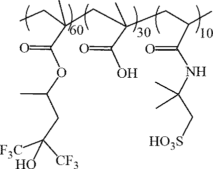

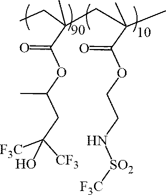

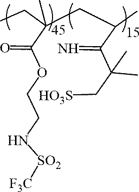

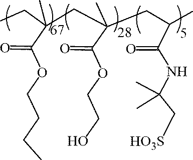

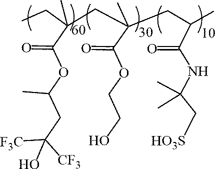

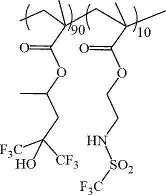

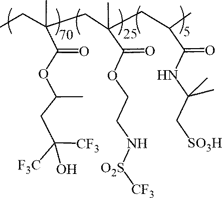

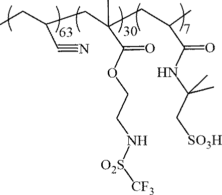

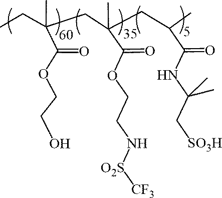

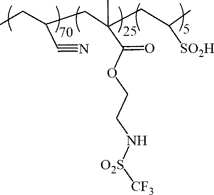

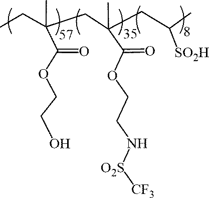

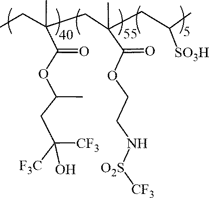

The one or more matrix polymers are typically present in the compositions in a combined amount of from 50 to 99.9 wt%, more typically from 85 to 95 wt%, based on total solids of the topcoat composition. The weight average molecular weight of the matrix polymer is typically less than 400,000, for example, from 5000 to 50,000, from 5000 to 15,000 or from 5000 to 25,000 Daltons.

The surface active polymer is provided in the topcoat compositions to provide beneficial surface properties at the topcoat/immersion fluid interface. In particular, the surface active polymer beneficially can provide desirable surface properties with respect to water, for example, one or more of improved static contact angle (SCA), receding contact angle (RCA), advancing contact angle (ACA) or sliding angle (SA) at the topcoat/immersion fluid interface. In particular, the surface active polymer can allow for a higher RCA, which can allow for faster scanning speeds and increased process throughput. A layer of the topcoat composition in a dried state preferably has a water receding contact angle of from 75 to 90°, and more preferably from 80 to 90°. The phrase “in a dried state” means containing 8 wt% or less of solvent, based on the entire composition.

The surface active polymer is preferably aqueous alkali soluble. The surface active polymer preferably has a lower surface energy than the matrix polymer. Preferably, the surface active polymer has a significantly lower surface energy than and is substantially immiscible with the matrix polymer, as well as any other polymers present in the topcoat composition. In this way, the topcoat composition can be self-segregating, wherein the surface active polymer migrates to the upper surface of the topcoat layer apart from other polymers during coating. The resulting topcoat layer is thereby rich in the surface active polymer at the topcoat layer upper surface which, in the case of an immersion lithography process is at the topcoat/immersion fluid interface. While the desired surface energy of the surface active polymer will depend on the particular matrix polymer and its surface energy, the surface active polymer surface energy is typically from 25 to 35 mN/m, preferably from 25 to 30 mN/m. The surface energy of the surface active polymer is typically from 5 to 25 mN/m less than that of the matrix polymer, preferably from 5 to 15 mN/m less than that of the matrix polymer.

The surface active polymer is fluorinated and comprises first polymerized units formed from a monomer of formula (1):

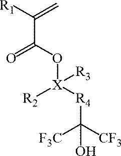

wherein: R₁ represents a hydrogen atom, a fluorine atom, a C1-C4 alkyl group, or a C1-C4 fluoroalkyl group, with a hydrogen atom or methyl being typical; R₂ and R₃ independently represent a hydrogen atom or a substituted or unsubstituted C1-C8 alkyl group; and R₄ represents a substituted or unsubstituted C1-C4 alkylene group. In formula (1), one or more of the following conditions are met: (i) at least one of R₂ and R₃ represents a substituted or unsubstituted C3-C8 cycloalkyl group; or (ii) at least one of R₂ and R₃ represents a substituted or unsubstituted C3-C8 alkyl group that forms a branched structure with the carbon atom to which R₂, R₃, R₄ are bonded; or (iii) R₂ and R₃ together form a ring. The total content of polymerized units of formula (1) in the surface active polymer is from 1 to 80 wt% based on total polymerized units of the surface active polymer.

Suitable monomers of general formula (I) include, for example, the following:

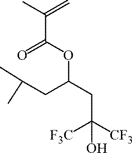

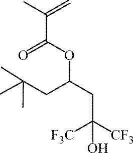

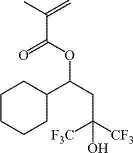

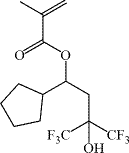

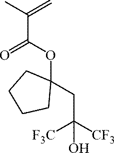

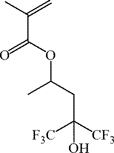

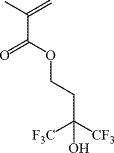

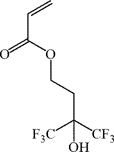

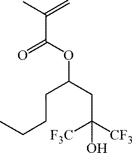

The surface active polymer further includes second polymerized units formed from a monomer of formula (2):

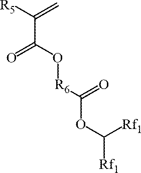

wherein: R₅ represents a hydrogen atom, a fluorine atom, a C1-C4 alkyl group, or a C1-C4 fluoroalkyl group, with a hydrogen atom or methyl being typical; R₆ represents a substituted or unsubstituted C1-C4 alkylene group; and Rf₁ independently represents a C1-C4 fluoroalkyl group, with trifluoromethyl being typical. The total content of polymerized units of formula (2) in the surface active polymer is typically from 20 to 99 wt% based on total polymerized units of the surface active polymer.

Suitable monomers of general formula (II) include, for example, the following:

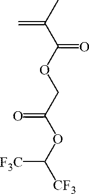

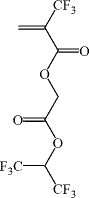

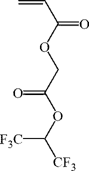

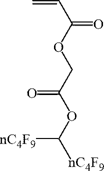

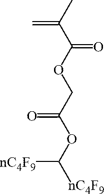

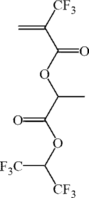

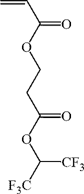

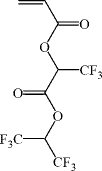

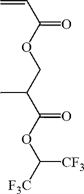

The surface active polymer may include one or more additional polymerized units that are different from the first and second polymerized units. Suitable additional polymerized units include, for example, those containing one or more group chosen from acid labile, base labile, sulfonamide, alkyl and ester groups. Preferably, such acid labile, base labile, sulfonamide, alkyl and ester groups are fluorinated.

Suitable additional unit types for use in the surface active polymer in accordance with the invention may include polymerized units of one or more of the following monomers:

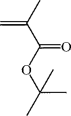

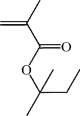

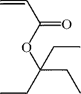

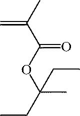

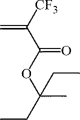

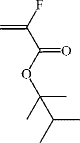

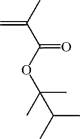

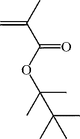

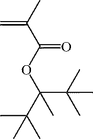 [SMILES: C=C(C)C(=O)OC(C)(C(C)(C)C)C(C)(C)C]

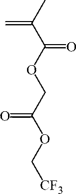

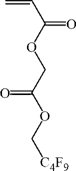

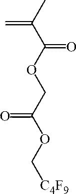

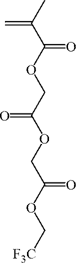 [SMILES: C=C(C)C(=O)OCC(=O)OCC(=O)OCC(F)(F)F]

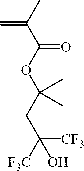 [SMILES: C=C(C)C(=O)OC(C)(C)CC(O)(C(F)(F)F)C(F)(F)F]

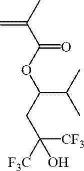 [SMILES: C=C(C)C(=O)OC(CC(O)(C(F)(F)F)C(F)(F)F)C(C)C]

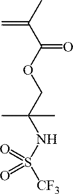 [SMILES: C=C(C)C(=O)OCC(C)(C)NS(=O)(=O)C(F)(F)F]

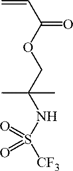 [SMILES: C=CC(=O)OCC(C)(C)NS(=O)(=O)C(F)(F)F]

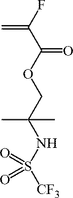 [SMILES: C=C(F)C(=O)OCC(C)(C)NS(=O)(=O)C(F)(F)F]

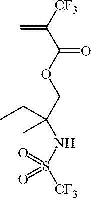 [SMILES: C=C(C(=O)OCC(C)(CC)NS(=O)(=O)C(F)(F)F)C(F)(F)F]

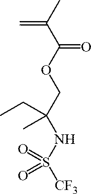 [SMILES: C=C(C)C(=O)OCC(C)(CC)NS(=O)(=O)C(F)(F)F]

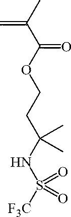 [SMILES: C=C(C)C(=O)OCCC(C)(C)NS(=O)(=O)C(F)(F)F]

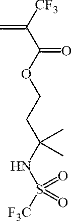 [SMILES: C=C(C(=O)OCCC(C)(C)NS(=O)(=O)C(F)(F)F)C(F)(F)F]

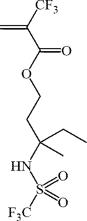 [SMILES: C=C(C(=O)OCCC(C)(CC)NS(=O)(=O)C(F)(F)F)C(F)(F)F]

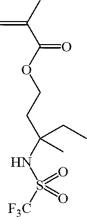 [SMILES: C=C(C)C(=O)OCCC(C)(CC)NS(=O)(=O)C(F)(F)F]

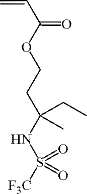 [SMILES: C=CC(=O)OCCC(C)(CC)NS(=O)(=O)C(F)(F)F]

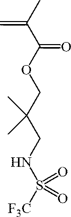 [SMILES: C=C(C)C(=O)OCC(C)(C)CNS(=O)(=O)C(F)(F)F]

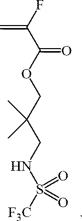

Exemplary polymers useful as the surface active polymer include, for example, the following:

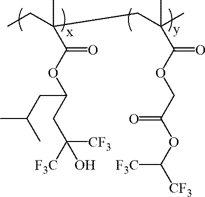

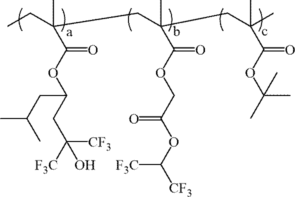

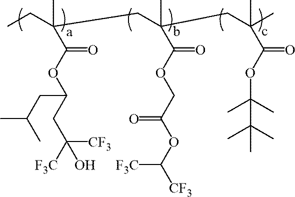

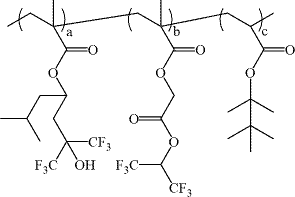

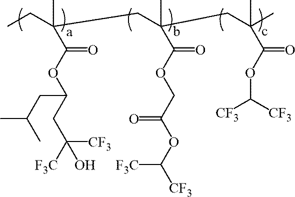

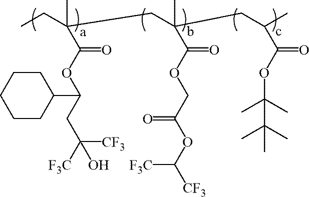

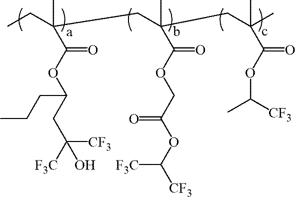

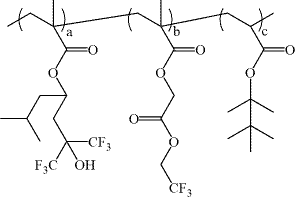

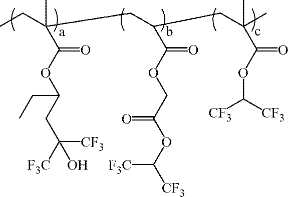

wherein x is frowem 2 to 99 wt%, y is from 1 to 98 wt%, a is from 2 to 98 wt%, and b and c are each from 1 to 97 wt%, wherein the sum of x and y is 100 wt%, and the sum of a, b and c is 100 wt%.

The surface active polymer lower limit for immersion lithography is generally dictated by the need to prevent leaching of the photoresist components. The surface active polymer is present in the compositions in an amount of from 0.1 to 30 wt%, more typically from 3 to 20 wt% or 5 to 15 wt%, based on total solids of the topcoat composition. The weight average molecular weight Mw of the surface active polymer is typically less than 400,000, preferably from 5000 to 50,000, more preferably from 5000 to 25,000 Daltons.

Optional additional polymers can be present in the topcoat compositions. For example, one or more additional polymers can be provided for purposes of tuning the resist feature profile and/or for controlling resist top loss. Additional polymers are typically miscible with the matrix polymer and substantially immiscible with the surface active polymer such that the surface active polymer can self-segregate from the other polymers to the topcoat surface away from the topcoat/photoresist interface. In accordance with a preferred aspect, the photoresist topcoat composition includes a third polymer that is fluorinated and is different from the matrix polymer and the surface active polymer. In accordance with a further preferred aspect, the photoresist topcoat composition includes such third polymer that is fluorinated and also a fourth polymer that is different from the matrix polymer, the surface active polymer, and the third polymer.

The organic-based solvent system comprises an ester solvent and one or more additional organic solvents. “Organic-based” means that the solvent system includes greater than 50 wt% organic solvent, typically from 90 to 100 wt%, more typically from 99 to 100 wt%, or 100 wt% organic solvent, not inclusive of residual water or other contaminants which may, for example, be present in an amount of from 0.05 to 1 wt%, based on the total solvent. Typical solvent materials to formulate and cast a topcoat composition are any which dissolve or disperse the components of the topcoat composition but do not appreciably dissolve an underlying photoresist layer. The solvent system includes a mixture of different solvents, for example, two, three or more solvents.

Preferred ester solvents include those represented by general formula (I):

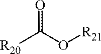

wherein: R₂₀ is chosen from C1 to C8 alkyl and R₂₁ is chosen from C3 to C8 alkyl. The total number of carbon atoms in R₂₀ and R₂₁ taken together is preferably greater than 5. Suitable such ester solvents include, for example, isoamyl acetate, propyl pentanoate, isopropyl pentanoate, isopropyl 3-methylbutanoate, isopropyl 2-methylbutanoate, isopropyl pivalate, isobutyl isobutyrate, 2-methylbutyl isobutyrate, 2-methylbutyl 2-methylbutanoate, 2-methylbutyl 2-methylhexanoate, 2-methylbutyl heptanoate, hexyl heptanoate, n-butyl n-butyrate, isoamyl n-butyrate, isoamyl isovalerate, and combinations thereof. Of these, isobutyl isobutyrate and isoamyl acetate are preferred. While the desired boiling point of the ester solvent will depend on other components of the solvent system, a boiling point from 140 to 180° C. is typical. The ester solvent is typically present in an amount of from 10 to 70 wt%, preferably from 20 to 60 wt%, more preferably from 30 to 50 wt%, based on the solvent system.

The solvent system includes one or more additional organic solvents. Without limitation, suitable additional solvents include, for example, alcohols, ethers, alkanes, ketones, and combinations thereof.

Suitable alcohols include, for example, C4 to C10 monovalent alcohols, such as n-butanol, isobutanol, 2-methyl-1-butanol, isopentanol, 2,3-dimethyl-1-butanol, 4-methyl-2-pentanol, isohexanol, isoheptanol, 1-octanol, 1-nonanol and 1-decanol, and mixtures thereof. Of these, 4-methyl-2-pentanol and 2-methyl-1-butanol are preferred. Preferably, the solvent system includes an alcohol solvent, which is typically present in an amount of from 30 to 80 wt%, more typically from 40 to 60 wt%, based on the solvent system. The boiling point of the alcohol is typically less than that of the ester solvent, with a boiling point of from 120 to 140° C. being typical.

Suitable ether solvents include, for example, hydroxy alkyl ethers, such as those of the following general formula (II):

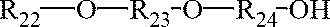

wherein R₂₂ is an optionally substituted C1 to C2 alkyl group, and R₂₃ and R₂₄ are independently chosen from optionally substituted C2 to C4 alkyl groups, and mixtures of such hydroxy alkyl ethers including isomeric mixtures. Exemplary hydroxy alkyl ethers include dialkyl glycol mono-alkyl ethers and isomers thereof, for example, diethylene glycol monomethyl ether, dipropylene glycol monomethyl ether, tripropylene glycol monomethyl ether, isomers thereof and mixtures thereof. Of these, dipropylene glycol monomethyl ether and tripropylene glycol monomethyl ether are preferred. Preferably, the solvent system includes a hydroxy alkyl ether solvent, which is typically present in an amount of from 3 to 15 wt% based on the solvent system. It is typical for the hydroxy alkyl ether to have a higher boiling point than the other components of the solvent system, with a boiling point of from 170 to 200° C. being typical. The hydroxy alkyl ether solvent can thereby facilitate phase separation of the surface active polymer from other polymers in the topcoat composition during the coating process, to provide a self-segregating topcoat structure. The higher boiling point hydroxy alkyl ether solvent can also reduce or prevent a tip drying effect during coating.

Other suitable ether solvents include, for example, alkyl ethers such as those of the formula (III):

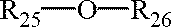

wherein R₂₅ and R₂₆ are independently chosen from C2 to C8 alkyl, preferably from C3 to C6 alkyl, and more preferably from C4 to C5 alkyl. Suitable alkyl ethers include, for example, isobutyl ether, isopentyl ether, isobutyl isohexyl ether, and mixtures thereof. Suitable alkane solvents include, for example, C8 to C12 n-alkanes, for example, n-octane, n-decane and dodecane, isomers thereof, and mixtures thereof. Suitable ketone solvents include, for example, acetone, methylethyl ketone, cyclohexanone, 2-heptanone, and mixtures thereof. The alkyl ether solvent, alkane solvent, and ketone solvent if used can independently be present, for example, in an amount of from 10 to 70 wt% based on the solvent system.

Particularly preferred are solvent systems that have three solvents, for example, those including an ester solvent, an alcohol solvent, and a hydroxy alkyl ether solvent. Particularly preferred solvent systems include: isobutyl isobutyrate, 4-methyl-2-pentanol, and dipropylene glycol monomethyl ether; isobutyl isobutyrate, 2-methyl-1-butanol, and tripropylene glycol monomethyl ether; isoamyl acetate, 4-methyl-2-pentanol, and dipropylene glycol monomethyl ether; and isoamyl acetate, 4-methyl-2-pentanol, and tripropylene glycol monomethyl ether.

The topcoat compositions may comprise one or more other optional components. For example, the compositions can include one or more of actinic and contrast dyes for enhancing antireflective properties, anti-striation agents, and the like. Such optional additives if used are typically present in the composition in minor amounts such as from 0.1 to 10 wt% based on total solids of the topcoat composition.

The topcoat compositions of the invention are substantially free of photoacid generator compounds (PAGs). The presence of PAGs, or an excessive PAG content, in the topcoat compositions may give rise to leaching of components of an underlying photoresist layer into the immersion fluid. Such leaching can contaminate the optical lens of the exposure tool, and cause a change in the effective refractive index and transmission properties of the immersion fluid. As used herein, “substantially free” means no more than 1 wt%, and typically less than 0.5 wt%, less than 0.1 wt%, or 0 wt%, based on total solids of the topcoat composition.

The topcoat compositions of the invention are preferably substantially free of base quencher compounds, for example, amine compounds, such as are commonly used in photoresist compositions. The conjugated acids of such base quencher compounds typically have a pKa > 0. The presence of base quenchers in the topcoat composition may prevent polymer deprotection in exposed regions of an underlying photoresist layer, which may result in bridging defects.

Topcoat layers formed from the compositions typically have an index of refraction of 1.4 or greater at 193 nm, preferably 1.47 or greater at 193 nm. The index of refraction can be tuned by changing the composition of the matrix polymer, the surface active polymer, or other components of the overcoat composition. For example, increasing the relative amount of organic content in the overcoat composition may provide increased refractive index of the layer. Preferred overcoat composition layers will have a refractive index between that of the immersion fluid and the photoresist at the target exposure wavelength.

The photoresist topcoat compositions can be prepared following known procedures. For example, the compositions can be prepared by dissolving solid components of the composition in the solvent components. The desired total solids content of the compositions will depend on factors such as the particular polymers in the composition and desired final layer thickness. Preferably, the solids content of the overcoat compositions is from 1 to 10 wt%, more preferably from 1 to 5 wt%, based on the total weight of the composition. The viscosity of the entire composition is typically from 1.5 to 2 centipoise (cp).

### Photoresist Compositions

Photoresist compositions useful in the methods of the invention include chemically-amplified photoresist compositions comprising a matrix polymer that is acid-sensitive, meaning that as part of a layer of the photoresist composition, the polymer and composition layer undergo a change in solubility in a developer as a result of reaction with acid generated by a photoacid generator following softbake, exposure to activating radiation and post exposure bake. The resist formulation can be positive-acting or negative-acting, but is typically positive-acting. In positive-type photoresists, the change in solubility is typically brought about when acid-labile groups such as photoacid-labile ester or acetal groups in the matrix polymer undergo a photoacid-promoted deprotection reaction on exposure to activating radiation and heat treatment. Suitable photoresist compositions useful for the invention are commercially available

For imaging at wavelengths such as 193 nm, the matrix polymer is typically substantially free (e.g., less than 15 mole%) or completely free of phenyl, benzyl or other aromatic groups where such groups are highly absorbing of the radiation. Suitable polymers that are substantially or completely free of aromatic groups are disclosed in European application EP930542A1 and U.S. Pat. Nos. 6,692,888 and 6,680,159, all of the Shipley Company. Preferable acid-labile groups include, for example, acetal groups or ester groups that contain a tertiary non-cyclic alkyl carbon (e.g., t-butyl) or a tertiary alicyclic carbon (e.g., methyladamantyl) covalently linked to a carboxyl oxygen of an ester of the matrix polymer.

Suitable matrix polymers further include polymers that contain (alkyl)acrylate units, preferably including acid-labile (alkyl)acrylate units, such as t-butyl acrylate, t-butyl methacrylate, methyladamantyl acrylate, methyladamantyl methacrylate, ethylfenchyl acrylate, ethylfenchyl methacrylate, and the like, and other non-cyclic alkyl and alicyclic (alkyl)acrylates. Such polymers have been described, for example, in U.S. Pat. No. 6,057,083, European Published Applications EP01008913A1 and EP00930542A1, and U.S. Pat. No. 6,136,501. Other suitable matrix polymers include, for example, those which contain polymerized units of a non-aromatic cyclic olefin (endocyclic double bond) such as an optionally substituted norbornene, for example, polymers described in U.S. Pat. Nos. 5,843,624 and 6, 048,664. Still other suitable matrix polymers include polymers that contain polymerized anhydride units, particularly polymerized maleic anhydride and/or itaconic anhydride units, such as disclosed in European Published Application EP01008913A1 and U.S. Pat. No. 6,048,662.

Also suitable as the matrix polymer is a resin that contains repeat units that contain a heteroatom, particularly oxygen and/or sulfur (but other than an anhydride, i.e., the unit does not contain a keto ring atom). The heteroalicyclic unit can be fused to the polymer backbone, and can comprise a fused carbon alicyclic unit such as provided by polymerization of a norbornene group and/or an anhydride unit such as provided by polymerization of a maleic anhydride or itaconic anhydride. Such polymers are disclosed in PCT/US01/14914 and U. S. Pat. No. 6,306,554. Other suitable heteroatom group-containing matrix polymers include polymers that contain polymerized carbocyclic aryl units substituted with one or more heteroatom (e.g., oxygen or sulfur) containing groups, for example, hydroxy naphthyl groups, such as disclosed in U.S. Pat. No. 7,244,542.

Blends of two or more of the above-described matrix polymers can suitably be used in the photoresist compositions.

Suitable matrix polymers for use in the photoresist compositions are commercially available and can be readily made by persons skilled in the art. The matrix polymer is present in the resist composition in an amount sufficient to render an exposed coating layer of the resist developable in a suitable developer solution. Typically, the matrix polymer is present in the composition in an amount of from 50 to 95 wt% based on total solids of the resist composition. The weight average molecular weight M_{w} of the matrix polymer is typically less than 100,000, for example, from 5000 to 100,000, more typically from 5000 to 15,000.

The photoresist composition further comprises a photoactive component such as a photoacid generator (PAG) employed in an amount sufficient to generate a latent image in a coating layer of the composition upon exposure to activating radiation. For example, the photoacid generator will suitably be present in an amount of from about 1 to 20 wt% based on total solids of the photoresist composition. Typically, lesser amounts of the PAG will be suitable for chemically amplified resists as compared with non-chemically amplified materials. Suitable PAGs are known in the art of chemically amplified photoresists and include, for example, those described above with respect to the topcoat composition.

Suitable solvents for the photoresist compositions include, for example: glycol ethers such as 2-methoxyethyl ether (diglyme), ethylene glycol monomethyl ether, and propylene glycol monomethyl ether; propylene glycol monomethyl ether acetate; lactates such as methyl lactate and ethyl lactate; propionates such as methyl propionate, ethyl propionate, ethyl ethoxy propionate and methyl-2-hydroxy isobutyrate; Cellosolve esters such as methyl Cellosolve acetate; aromatic hydrocarbons such as toluene and xylene; and ketones such as acetone, methylethyl ketone, cyclohexanone and 2-heptanone. A blend of solvents such as a blend of two, three or more of the solvents described above also are suitable. The solvent is typically present in the composition in an amount of from 90 to 99 wt%, more typically from 95 to 98 wt%, based on the total weight of the photoresist composition.

The photoresist compositions can also include other optional materials. For example, the compositions can include one or more of actinic and contrast dyes, anti-striation agents, plasticizers, speed enhancers, sensitizers, and the like. Such optional additives if used are typically present in the composition in minor amounts such as from 0.1 to 10 wt% based on total solids of the photoresist composition.

A preferred optional additive of the resist compositions is an added base. Suitable bases are known in the art and include, for example, linear and cyclic amides and derivatives thereof such as N,N-bis(2-hydroxyethyl)pivalamide, N,N-Diethylacetamide, N1,N1,N3,N3-tetrabutylmalonamide, 1-methylazepan-2-one, 1-allylazepan-2-one and tert-butyl 1,3-dihydroxy-2-(hydroxymethyl)propan-2-ylcarbamate; aromatic amines such as pyridine, and di-tert-butyl pyridine; aliphatic amines such as triisopropanolamine, n-tert-butyldiethanolamine, tris(2-acetoxy-ethyl) amine, 2,2’,2”,2‴-(ethane-1,2-diylbis(azanetriyl))tetraethanol, and 2-(dibutylamino)ethanol, 2,2’,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate and N (2-acetoxyethyl) morpholine. The added base is suitably used in relatively small amounts, for example, from 0.01 to 5 wt%, preferably from 0.1 to 2 wt%, based on total solids of the photoresist composition.

The photoresists can be prepared following known procedures. For example, the resists can be prepared as coating compositions by dissolving the solid components of the photoresist in the solvent component. The desired total solids content of the photoresist will depend on factors such as the particular polymers in the composition, final layer thickness and exposure wavelength. Typically the solids content of the photoresist varies from 1 to 10 wt%, more typically from 2 to 5 wt%, based on the total weight of the photoresist composition.

### Lithographic Processing

Liquid photoresist compositions can be applied to a substrate such as by spin-coating, dipping, roller-coating or other conventional coating technique, with spin-coating being typical. When spin coating, the solids content of the coating solution can be adjusted to provide a desired film thickness based upon the specific spinning equipment utilized, the viscosity of the solution, the speed of the spinner and the amount of time allowed for spinning.

Photoresist compositions used in the methods of the invention are suitably applied to a substrate in a conventional manner for applying photoresists. For example, the compositions may be applied over silicon wafers or silicon wafers coated with one or more layers and having features on a surface for the production of microprocessors or other integrated circuit components. Aluminum-aluminum oxide, gallium arsenide, ceramic, quartz, copper, glass substrates and the like may also be suitably employed. The photoresist compositions are typically applied over an antireflective layer, for example, an organic antireflective layer.

A topcoat composition of the invention can be applied over the photoresist composition by any suitable method such as described above with reference to the photoresist compositions, with spin-coating being typical.

Following coating of the photoresist onto a surface, it may be heated (softbaked) to remove the solvent until typically the photoresist coating is tack free, or the photoresist layer may be dried after the topcoat composition has been applied and the solvent from both the photoresist composition and topcoat composition layers substantially removed in a single thermal treatment step.

The photoresist layer with overcoated topcoat layer is then exposed through a patterned photomask to radiation activating for the photoactive component of the photoresist. The exposure is typically conducted with an immersion scanner but can alternatively be conducted with a dry (non-immersion) exposure tool.

During the exposure step, the photoresist composition layer is pattern-wise exposed to activating radiation to create a difference in solubility between exposed and unexposed regions. Reference herein to exposing a photoresist composition to radiation that is activating for the composition indicates that the radiation is capable of forming a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of less than 300 nm, such as 248 nm, 193 nm or an EUV wavelength such as 13.5 nm, with 193 nm immersion lithography being typical. Following exposure, the layer of the composition is typically baked at a temperature ranging from about 70° C. to about 160° C.

Thereafter, the film is developed, typically by treatment with an aqueous base developer chosen, for example, from: quaternary ammonium hydroxide solutions such as a tetra-alkyl ammonium hydroxide solutions, typically a 0.26 N tetramethylammonium hydroxide; amine solutions such as ethyl amine, n-propyl amine, diethyl amine, di-n-propyl amine, triethyl amine, or methyldiethyl amine; alcohol amines such as diethanol amine or triethanol amine; and cyclic amines such as pyrrole or pyridine. In general, development is in accordance with procedures recognized in the art.

Following development of the photoresist layer, the developed substrate may be selectively processed on those areas bared of resist, for example by chemically etching or plating substrate areas bared of resist in accordance with procedures known in the art. After such processing, the resist remaining on the substrate can be removed using known stripping procedures.

The following non-limiting examples are illustrative of the invention.

### EXAMPLES

### Polymer Synthesis

The following monomers were used to prepare polymers as described below. Monomer ratios in the examples are provided on a mole percentage (mol%) basis of the polymer.

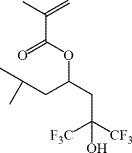 [SMILES: C=C(C)C(=O)OC(CC(C)C)CC(O)(C(F)(F)F)C(F)(F)F]

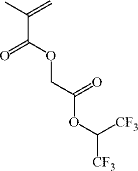 [SMILES: C=C(C)C(=O)OCC(=O)OC(C(F)(F)F)C(F)(F)F]

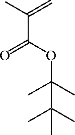

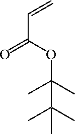

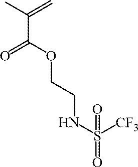 [SMILES: C=C(C)C(=O)OCCNS(=O)(=O)C(F)(F)F]

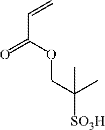

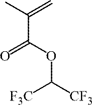

Compositional ratios as determined by NMR, weight average molecular weight Mw, and polydispersity (PDI = Mw/Mn) determined by the polystyrene equivalent value as measured by gel permeation chromatography (GPC) for the polymers are shown in Table 1.

### Example 1 (Polymer P1)

A reaction vessel was charged with 618.4 g methyl isobutyl carbinol (MIBC), which was heated over a period of about 2.5 hours period to 90° C. A monomer feed solution was prepared by combining 267.6 g MIBC and 263.2 g monomer M6. An initiator feed solution was prepared by combining 340.2 g MIBC and 10.52 g V-601 initiator (FUJIFILM Wako Pure Chemical Corp.). When the MIBC in the vessel reached 89.5° C., the monomer feed solution and initiator feed solution were introduced into the reaction vessel and fed over a period of 2 hours and 3 hours, respectively. The reaction vessel was maintained at 90° C. for an additional 7 hours with agitation, and was then allowed to cool to room temperature to yield polymer P1 at 16.5 wt% solids.

### Example 2 (Polymer P2)

A reaction vessel was charged with 32.53 g propylene glycol methyl ether (PGME) and heated to 97° C. A monomer feed solution was prepared by combining 28.10 g PGME, 31.17 g monomer M6, and 3.28 g monomer M7. An initiator feed solution was prepared by combining 4.43 g PGME and 0.49 g VAZO-67 initiator (FUJIFILM Wako Pure Chemical Corp.). The monomer feed solution and initiator feed solution were introduced into the reaction vessel and fed over a period of 2 hours and 3 hours, respectively. The reaction vessel was maintained at 97° C. for an additional 4 hours with agitation, and was then allowed to cool to room temperature to yield polymer P2.

### Example 3 (Polymer P3)

A reaction vessel was charged with 30.0 g isobutylisobutyrate (IBIB) and heated to 99° C. A monomer feed solution was prepared by combining 28.57 g IBIB, 40.0 g monomer M1, and 1.44 g V-601 initiator (FUJIFILM Wako Pure Chemical Corp.). The monomer feed solution was introduced into the reaction vessel over a period of 2 hours, and the reaction mixture was heated for an additional 5 hours. The reaction mixture was then allowed to cool to room temperature to yield polymer P3.

### Example 4 (Polymer P4)

A reaction vessel was charged with 7.0 g PGME and heated to 90° C. A monomer feed solution was prepared by combining 6.6 g PGME, 21.21 g monomer M1, 9.24 g monomer M2, 11.55 g monomer M4, and 1.05 g V-601 initiator (FUJIFILM Wako Pure Chemical Corp.). The monomer feed solution was introduced into the reaction vessel over a period of 1.5 hours, and the reaction mixture was heated for an additional 3 hours. The reaction mixture was then allowed to cool to room temperature. The polymer solution was precipitated in a 2:1 Methanol/H₂O solvent blend to yield polymer P4 as a solid.

### Examples 5-17 (Polymers P5-P17)

Polymers P5-P 17 were synthesized in a similar manner to the method described for Polymer P4.

TABLE 1

| Example | Polymer | Monomers (mol%*) | | | | | | | Mw (kDa) | PDI |
|---|---|---|---|---|---|---|---|---|---|---|
| | | M1 | M2 | M3 | M4 | M5 | M6 | M7 | | |
| 1 | P1 | | | | | 100 | | | 8.73 | 1.72 |
| 2 | P2 | | | | | 95 | 5 | | 17.06 | 2.42 |
| 3 | P3 | 100 | | | | | | | 6.55 | 1.6 |
| 4 | P4 | 42 | 20 | 38 | | | | | 15.7 | 1.66 |
| 5 | P5 | | 50 | 50 | | | | | 9.42 | 1.82 |
| 6 | P6 | 65 | 15 | 20 | | | | | 14.5 | 1.99 |
| 7 | P7 | 40 | 30 | 30 | | | | | 15.7 | 1.66 |
| 8 | P8 | 20 | 50 | 30 | | | | | 12.64 | 1.78 |
| 9 | P9 | 15 | 50 | 35 | | | | | 14.02 | 1.84 |
| 10 | P10 | 10 | 30 | 30 | | | | 30 | 12.99 | 2.01 |
| 11 | P11 | 5 | 50 | 45 | | | | | 13.1 | 2.02 |
| 12 | P12 | 5 | 60 | 35 | | | | | 12.5 | 2.5 |
| 13 | P13 | 5 | 80 | 15 | | | | | 11.8 | 3.1 |
| 14 | P14 | 5 | 50 | | 45 | | | | 10.78 | 2.32 |
| 15 | P15 | 65 | 15 | | 20 | | | | 13.8 | 1.95 |
| 16 | P16 | 5 | 80 | | 15 | | | | 12.25 | 1.75 |
| 17 | P17 | 65 | 35 | | | | | | 11.74 | 1.95 |

* = theoretical mol% based on total polymer and calculated based on monomer ratios.

### Topcoat Composition Preparation:

Topcoat compositions were formulated by adding solid components to a solvent system in the amounts shown in Table 2. Each mixture was filtered through a 0.2 µm PTFE disk. In addition to polymers described above, the solid components included a polymer P18 as follows: P18 [Mw = 10.76 kDa, PDI = 2.3]

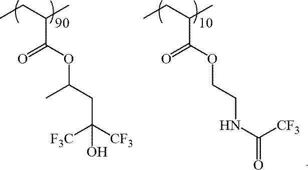

### Dewet Coating Defect Testing:

Coating defect testing was carried out by coating topcoat compositions with a TEL Lithius wafer track on 300 mm silicon wafers primed with hexmethyldisilazane at 120° C. for 30 seconds. The compositions were coated to a thickness of 385 Å using a dispense time of 1.6 seconds and a softbake at 90° C. for 60 seconds. Images of the coated topcoat layers were obtained with a KLA-Tencor Surfscan SP2 wafer surface inspection tool. The images were visually inspected for dewet defects, which are coating discontinuities (i.e., a lack of coating) that appear as spikes at the wafer periphery extending in a radial direction. A finding of zero dewet defects on a wafer was considered to be a good result (◯) and one or more coating defects was considered to be a bad result (×). The results are shown in Table 2.

### Dynamic Receding Contact Angle (dRCA) Testing:

200 mm silicon wafers were primed on a TEL ACT-8 wafer track with hexamethyldisilazane (HMDS) at 120° C. for 30 seconds, coated with 385 Å of a respective topcoat composition, and softbaked at 90° C. for 60 seconds. The receding contact angle (RCA) for each of the topcoat compositions was measured on a Kruss contact angle goniometer using deionized Millipore filtered water. Measurements were carried out with a 50 µL drop size and a tilt speed of 1 unit/sec starting from a 0° (horizontal) tilt. RCA was measured at the beginning of lateral drop motion and at increasingly larger tilt table angles (TTA) at approximately 1° increments until the water drop rolled out of the camera view. Measurements taken at 20° TTA are reported. The results are shown in Table 2 and demonstrate that topcoat RCAs above 81° were achieved for the topcoat compositions of the invention.

TABLE 2

| Example | Topcoat Composition | Polymers | | | | | Solvents | | | dRCA | Coating Defects |
|---|---|---|---|---|---|---|---|---|---|---|---|
| | | (wt%*) | | | | | (wt%**) | | | (°) | |
| 18 | TC1 | P18 | P1 | | P3 | | S1 | S3 | S6 | 79.7 | ○ |
| (Comp) | | (53) | (36) | | (11) | | (53) | (41) | (6) | | |
| 19 | TC2 | P18 | P1 | | | P4 | S1 | S3 | S6 | 82.4 | × |
| (Comp) | | (53) | (36) | | | (11) | (53) | (41) | (6) | | |
| 20 | TC3 | P18 | P1 | P2 | P3 | P5 | S1 | S4 | S6 | 82 | × |
| (Comp) | | (51) | (26) | (9) | (10) | (4) | (53) | (41) | (6) | | |
| 21 | TC4 | P18 | P1 | | | P6 | S1 | S5 | S6 | 83.2 | ○ |
| | | (53) | (36) | | | (11) | (53) | (41) | (6) | | |
| 22 | TC5 | P18 | P1 | P2 | P3 | P7 | S1 | S4 | S6 | 82.2 | ○ |
| | | (52) | (17) | (17) | (10) | (4) | (53) | (41) | (6) | | |
| 23 | TC6 | P18 | P1 | P2 | P3 | P8 | S1 | S4 | S6 | 81.3 | ○ |
| | | (52) | (17) | (17) | (10) | (4) | (53) | (41) | (6) | | |
| 24 | TC7 | P18 | P1 | P2 | P3 | P9 | S1 | S4 | S6 | 81.5 | ○ |
| | | (52) | (17) | (17) | (10) | (4) | (53) | (41) | (6) | | |
| 25 | TC8 | P18 | P1 | P2 | P3 | P10 | S1 | S5 | S6 | 82.3 | ○ |
| | | (52) | (30) | (4) | (10) | (4) | (53) | (41) | (6) | | |
| 26 | TC9 | P18 | P1 | P2 | P3 | P11 | S1 | S4 | S6 | 82.9 | ○ |
| | | (52) | (17) | (17) | (10) | (4) | (53) | (41) | (6) | | |
| 27 | TC10 | P18 | | P2 | P3 | P12 | S1 | S4 | S6 | 82.8 | ○ |
| | | (52) | | (34) | (10) | (4) | (53) | (41) | (6) | | |
| 28 | TC11 | P18 | | P2 | P3 | P13 | S1 | S4 | S6 | 83.5 | ○ |
| | | (52) | | (34) | (10) | (4) | (53) | (41) | (6) | | |
| 29 | TC12 | P18 | P1 | P2 | | P14 | S1 | S4 | S6 | 81.7 | ○ |
| | | (53) | (27) | (9) | | (11) | (53) | (41) | (6) | | |
| 30 | TC13 | P18 | P1 | | | P15 | S1 | S5 | S7 | 83.9 | ○ |
| | | (53) | (36) | | | (11) | (53) | (41) | (6) | | |
| 31 | TC14 | P18 | P1 | | | P16 | S2 | S4 | S6 | 86 | ○ |
| | | (53) | (36) | | | (11) | (53) | (41) | (6) | | |
| 32 | TC15 | P18 | P1 | P2 | | P17 | S1 | S4 | S6 | 81.4 | ○ |
| | | (53) | (27) | (9) | | (11) | (53) | (41) | (6) | | |

Comp = Comparative Example;
* = wt% based on total solids;
** = wt% based on total solvent;
S1 = Methyl isobutyl carbinol;
S2 = 2-Methyl-1-Butanol;
S3 = Isoamyl ether;
S4 = Isobutyl isobutyrate;
S5 = Isoamyl acetate;
S6 = Dipropylene Glycol Monomethyl Ether.;
S7 = Tripropylene Glycol Monomethyl Ether;
o= No coating defects observed;
× = One or more coating defects observed;
polymer wt% based on total solids;
solvent wt% based on total solvent.

1. A photoresist topcoat composition, comprising:
a first polymer that is fluorinated, comprising:
first polymerized units formed from a monomer of formula (1): 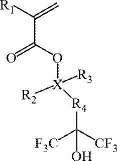
wherein: R₁ represents a hydrogen atom, a fluorine atom, a C1-C4 alkyl group, or a C1-C4 fluoroalkyl group; R₂ and R₃ independently represent a hydrogen atom or a substituted or unsubstituted C1-C8 alkyl group; R₄ represents a substituted or unsubstituted C1-C4 alkylene group; and X represents a carbon atom, wherein:
(i) at least one of R₂ and R₃ represents a substituted or unsubstituted C3-C8 cycloalkyl group; or
(ii) at least one of R₂ and R₃ represents a substituted or unsubstituted C3-C8 alkyl group that comprises a branched structure when taken with X; or
(iii) R₂ and R₃ together form a ring; and
second polymerized units formed from a monomer of formula (2): 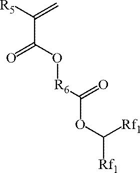
wherein: R₅ represents a hydrogen atom, a fluorine atom, a C1-C4 alkyl group, or a C1-C4 fluoroalkyl group; R₆ represents a substituted or unsubstituted C1-C4 alkylene group; and Rf₁ independently represents a C1-C4 fluoroalkyl group;
wherein: the total content of polymerized units of formula (1) in the first polymer is from 1 to 80 wt% based on total polymerized units of the first polymer; and wherein the first polymer is present in the composition in an amount of from 1 to 20 wt% based on total solids of the composition;
a second polymer; and
an organic-based solvent system comprising an ester solvent and one or more additional organic solvents;
wherein the composition is substantially free of photoacid generator compounds.

2. The photoresist topcoat composition of claim 1, wherein the one or more additional organic solvents comprise an alcohol solvent.

3. The photoresist topcoat composition of claim 2, wherein the ester solvent is isobutyl isobutyrate or isoamyl acetate and the alcohol solvent is methyl isobutyl carbinol.

4. The photoresist topcoat composition of claim 1, wherein the photoresist topcoat composition further comprises a third polymer that is fluorinated that is different from the first and second polymers.

5. The photoresist topcoat composition of claim 4, further comprising a fourth polymer that is different from the first, second and third polymers.

6. The photoresist topcoat composition of claim 1, wherein at least one of R₂ and R₃ represents a substituted or unsubstituted C3-C8 cycloalkyl group.

7. The photoresist topcoat composition of claim 1, wherein at least one of R₂ and R₃ represents a substituted or unsubstituted C3-C8 alkyl group that comprises a branched structure when taken with X.

8. The photoresist topcoat composition of claim 1, wherein each Rf₁ is a trifluoromethyl group.

9. A pattern formation method, comprising:
(a) forming a photoresist layer on a substrate;
(b) forming a photoresist topcoat layer on the photoresist layer;
(c) exposing the photoresist topcoat layer and the photoresist layer to activating radiation; and
(d) contacting the exposed topcoat layer and photoresist layer with a developer to form a resist pattern;
wherein the photoresist topcoat layer is formed from a photoresist topcoat composition comprising:
a first polymer that is fluorinated, comprising:
first polymerized units formed from a monomer of formula (1): 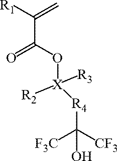
wherein: R₁ represents a hydrogen atom, a fluorine atom, a C1-C4 alkyl group, or a C1-C4 fluoroalkyl group; R₂ and R₃ independently represent a hydrogen atom or a substituted or unsubstituted C1-C8 alkyl group; R₄ represents a substituted or unsubstituted C1-C4 alkylene group; and X represents a carbon atom, wherein:
(i) at least one of R₂ and R₃ represents a substituted or unsubstituted C3-C8 cycloalkyl group; or
(ii) at least one of R₂ and R₃ represents a substituted or unsubstituted C3-C8 alkyl group that comprises a branched structure when taken with X; or
(iii) R₂ and R₃ together form a ring; and
second polymerized units formed from a monomer of formula (2): 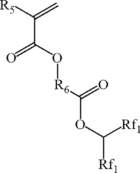
wherein: R₅ represents a hydrogen atom, a fluorine atom, a C1-C4 alkyl group, or a C1-C4 fluoroalkyl group; R₆ represents a substituted or unsubstituted C1-C4 alkylene group; and Rf₁ independently represents a C1-C4 fluoroalkyl group;
wherein: the total content of polymerized units of formula (1) in the first polymer is from 1 to 80 wt% based on total polymerized units of the first polymer; and wherein the first polymer is present in the composition in an amount of from 1 to 20 wt% based on total solids of the composition;
a second polymer; and
an organic-based solvent system comprising an ester solvent and one or more additional organic solvents;
wherein the composition is substantially free of photoacid generator compounds.

10. The method of claim 9, wherein the topcoat layer is formed by spin-coating, and the first polymer migrates to an upper surface of the topcoat layer during the spin-coating, wherein an upper surface of the topcoat layer consists essentially of the first polymer.

11. The method of claim 9, wherein the one or more additional organic solvents comprise an alcohol solvent.

12. The method of claim 11, wherein the ester solvent is isobutyl isobutyrate or isoamyl acetate and the alcohol solvent is methyl isobutyl carbinol.

13. The method of claim 9, wherein the photoresist topcoat composition further comprises a third polymer that is fluorinated that is different from the first and second polymers.

14. The method of claim 13, further comprising a fourth polymer that is different from the first, second and third polymers.

15. The method of claim 9, wherein at least one of R₂ and R₃ represents a substituted or unsubstituted C3-C8 cycloalkyl group.

16. The method of claim 9, wherein at least one of R₂ and R₃ represents a substituted or unsubstituted C3-C8 alkyl group that comprises a branched structure when taken with X.

17. The method of any of claim 9, wherein each Rf₁ is a trifluoromethyl group.
